(19) United States
(12) Patent Application Publication
(10) Pub. No.: US 2014/0355179 A1
(43) Pub. Date: Dec. 4, 2014

(54) METHOD OF PREVENTING CRACKING IN GLASS DISPLAY SCREENS

(71) Applicant: Spire Corporation, Bedford, MA (US)

(72) Inventor: Roger G. Little, Bedford, MA (US)

(21) Appl. No.: 13/909,588

(22) Filed: Jun. 4, 2013

(51) Int. Cl. H05K 5/03; H02N 13/00

(52) U.S. Cl. CPC H05K 5/03; H02N 13/00
USPC 361/679.01; 156/273.1

(57) ABSTRACT

A portable electronic device housing portion is applied to a cover glass. The cover glass is heated to generate ionic conductivity therein and the method includes anodic bonding the cover glass to the housing portion. Cooling the assembly induces compressive stress within the cover glass to increase its tensile strength. The process which seals the cover glass to the housing also strengthens the cover glass.

### FIELD OF THE INVENTION

This subject invention relates to portable electronic devices and housings therefore.

### BACKGROUND OF THE INVENTION

Modern portable electronic devices such as cellular telephones include a touch screen assembly behind a cover glass. See Published U.S. Application No. 2012/0281380 incorporated herein by this reference. One typical goal is to maximize the exposure of the cover glass (and the touch screen assembly) and to render the cover glass very thin (e.g., less than 3 mm thick).

According to the above referenced published patent application, adhesives are usually used to secure the cover glass to the housing. In the disclosure, the housing includes mounting brackets attached to housing side members. An adhesive is used to secure the cover glass to the mounting brackets.

When such a cellular telephone is dropped, the glass can easily crack and a crack at the periphery of the cover glass will propagate resulting in the cover glass shattering. Edge and corner cracking is common.

Using a softer, more pliant material for the cover glass is not possible due to the need for the cover glass to be resistant to scratching.

### SUMMARY OF THE INVENTION

In U.S. Pat. No. 4,393,105, also incorporated herein by this reference, two panes of glass were secured to an aluminum spacer frame to form a thermal pane window using anodic bonding. But, the aluminum spacer frame material was chosen specifically to have a very low yield strength so high stresses were not induced in the glass panes.

In this invention, in contrast, it is desirable to induce stress into the cover glass to increase its tensile strength and to prevent both cracking and crack propagation.

Conveniently, the anodic bonding process which secures the cover glass to the portable electronic device housing portion (side member, mounting rail, or internal metal frame) itself may result in induced compressive stress within the cover glass and thus the process which serves to secure the cover glass to the housing portion without the need for an adhesive also strengthens the cover glass.

Featured is a method comprising applying a portable electronic device housing portion to a cover glass which has been heated to generate ionic conductivity therein, and anodic bonding the cover glass to the housing portion. In cooling the assembly, compressive stress is induced within the cover glass to increase its tensile strength. The method may further include the step attaching a touch screen assembly to the cover glass. In one version, the cover glass includes silica glass or is sapphire. Heating the cover glass may include heating the cover glass to a temperature of 350° C.+/−100° C. Heating may occur in an oven or via a hot plate.

The step of inducing compressive stress within the cover glass may include choosing a housing portion material which has a coefficient of thermal expansion substantially higher than the coefficient of thermal expansion of the cover glass. Preferably, the step of inducing compressive stress within the cover glass further includes choosing a housing portion material which does not have too low or too high a yield strength. In one example, the housing portion is made of aluminum.

Anodic bonding the cover glass to the housing may include placing a first electrode on the cover glass and a second electrode on the housing portion. In some examples, the housing portion is side member, a mounting rail, or a metal frame about the cover glass.

Also featured is a method comprising heating a glass portion to generate ionic conductivity therein and heating a housing portion to expand it to a greater extent than the glass portion. When the housing portion is so expanded, it is bonded to the glass portion at the periphery thereof using anodic bonding. The assembly is cooled and the housing portion contracts to a greater extent than the glass portion which induces compressive stress within the glass portion at the periphery thereof.

Also featured is a portable electronic device comprising a housing portion, a cover glass, and an electrostatic bond between the housing portion and the cover glass at the periphery of the cover glass. The housing portion induces compressive stress within the cover glass at its periphery increasing its tensile strength. The portable electronic device may further include a touch screen assembly secured to the cover glass.

The subject invention, however, in other embodiments, need not achieve all these objectives and the claims hereof should not be limited to structures or methods capable of achieving these objectives. The references Bonding Properties of Metals Anodically Bonded to Glass, Briand, Weber, deRooij; Sensors and Actuators A: Physical 114 issues 2-3, 543-549, 2004; Anodic Bonding of Glass to Aluminum, Schjolberg-Henrikson, Poppe, Moe, Storas, Taklo, Wang, Jacobsen; Micorsyst Technol (2006) 12: 441-449 DOI 10.1007/s00542-005-0040-8; Interfacial Phenomena in Electric Field-Assisted Anodic Bonding of Kovar/Al Film-Glass, Chen, Gu, Dong, Trans. Nonferrous Met. Soc. China Vol. 11 No. 5, Oct. 2001; and Field Assisted Glass Sealing, Wallis; and Electrocomponent Science and Technology 1975, Vol. 2, No. 1 pp. 44-53 are all incorporated herein by this reference.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic three dimensional top view showing one example of a portable electronic device housing and cover glass combination;

FIG. 2 is a schematic three dimensional top view showing a cover glass surrounded by a metallic frame in accordance with examples of the invention;

FIG. 3 is a schematic cross-sectional end view of a cover glass supported by housing frame rails;

FIG. 4 is a schematic three dimensional partially cross-sectional view showing a method of Anodic bonding the cover glass of FIG. 3 to the housing rails;

FIG. 5 is a schematic three dimensional view showing a cover glass anodically bonded to a portable electronic device side housing member;

FIG. 6 is a schematic partially cross-sectional view showing another example of portable electronic device cover glass being anodically bonded to a housing portion; and

FIG. 7 is a flow chart depicting the primary steps associated with an example of a manufacturing process in accordance with the invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer

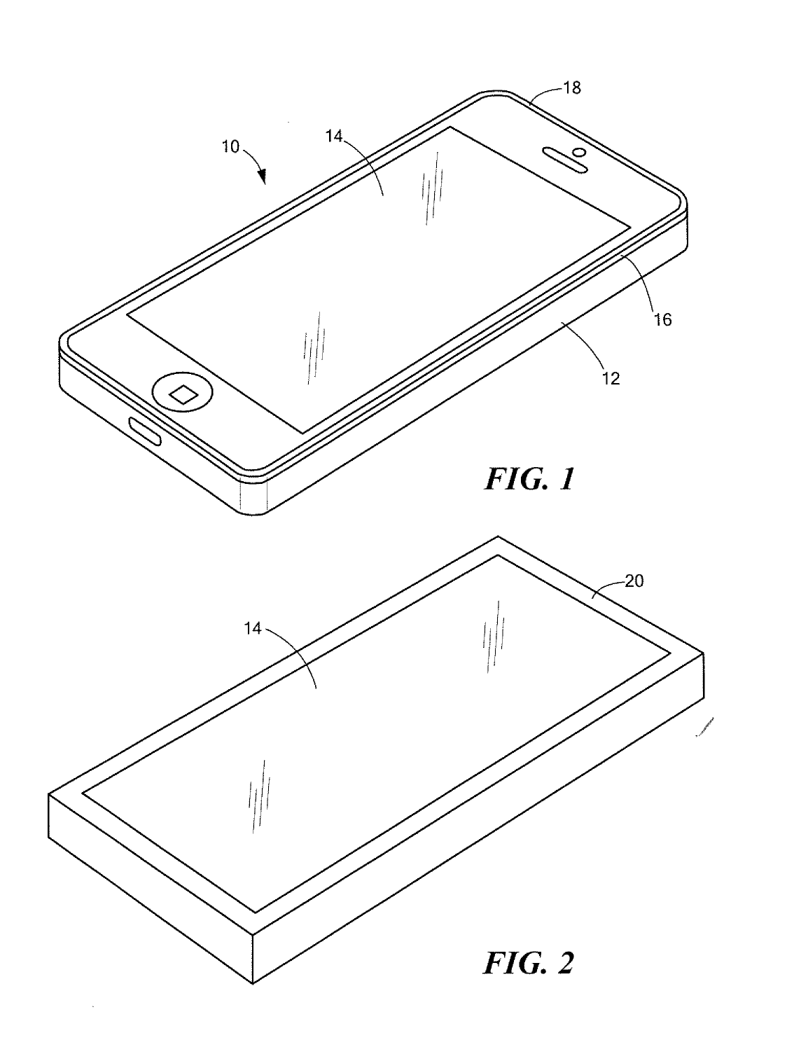

FIG. 1 shows portable electronic device 10 with housing 12 and cover glass 14. Behind cover glass 14 it a touch screen assembly as, for example, depicted in published U.S. Patent Application No. 2012/0281380. The housing also includes various electronic components therein. Here, the housing includes aluminum portion 16 with very thin top edge 18. Cover glass 14 is bonded to aluminum portion 16 via an anodic bonding technique which, in addition to connecting and sealing glass 14 with respect to the housing, induces compressive stress within cover glass 14 increasing its tensile strength to prevent cracking and crack propagation. The compressive stress induced is present at least at the periphery of the cover glass at and proximate to the regions where the cover glass is anodically bonded to the aluminum housing portion.

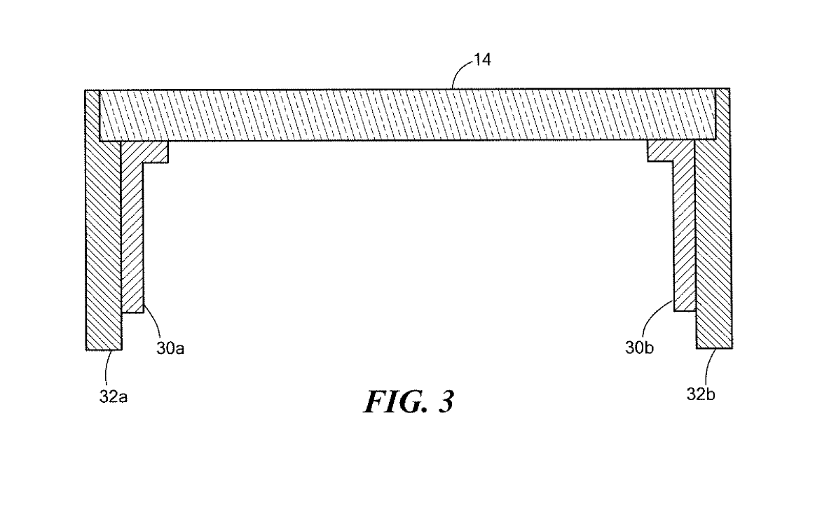

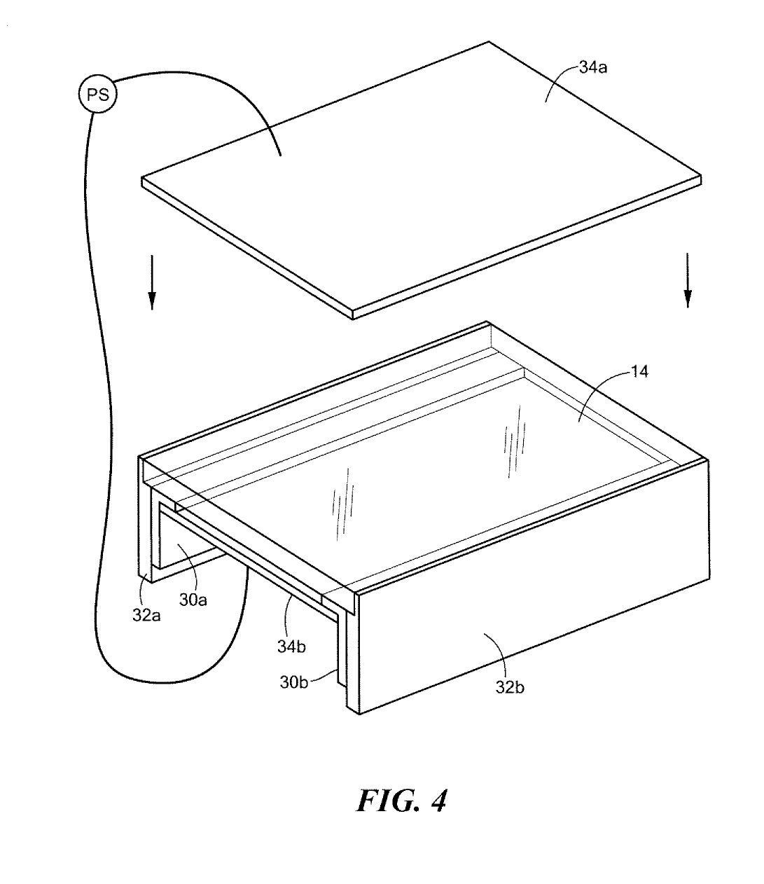

In FIG. 2, cover glass 14 is connected to metal frame 20 via anodic bonding. This metal frame may then be attached to another housing component. In FIGS. 3-4, cover glass 14 is married to mounting rails 30a, and 30b which are affixed (e.g., welded) to housing side members 32a, 32b. Electrode 34a is placed on glass 14 and electrode 34b contacts rails 30a, 30b for anodic bonding of glass 14 to rails 30a, 30b. Similarly, anodic bonding may be used to secure glass 14 to side members 32a, 32b.

Electrode 34b may be a plate shaped member or a frame shaped member. Alternatively, a probe with a small tip may be used. The probe may be static or may be maneuvered to contact different parts of the rails, for example.

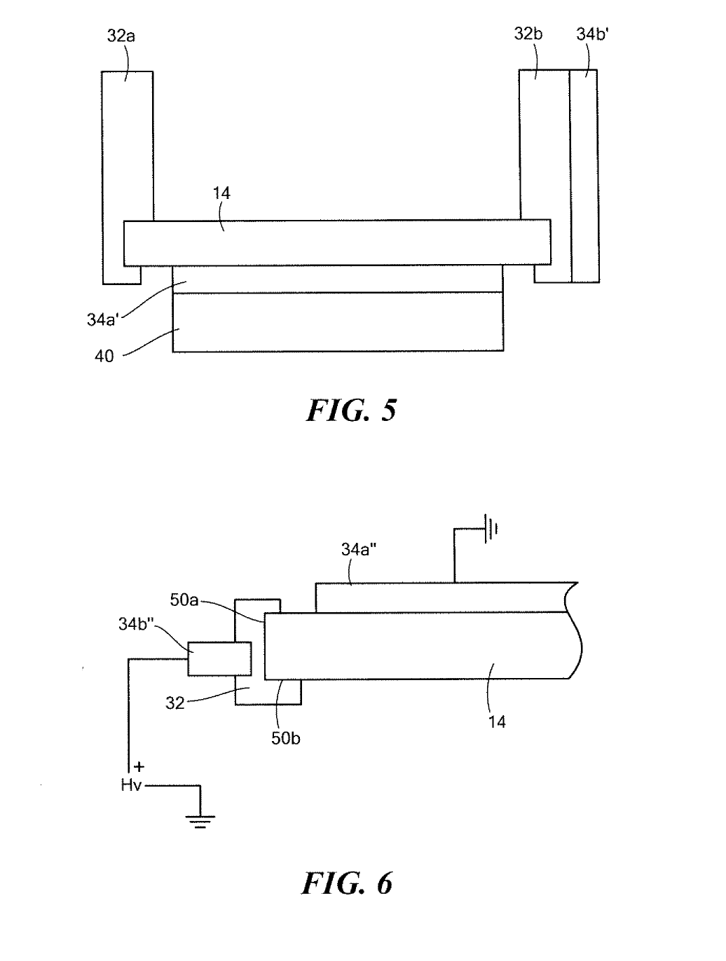

In FIG. 5, cover glass 14 is mounted to housing side portions 32a, 32b via anodic bonding using electrodes 34a′ and 34b′ and hot plate 40. In FIG. 6, housing portion 32 (a side wall, a mounting rail, or a frame member) is secured to cover glass 14 using electrodes 34a″ and 34b″. See U.S. Pat. No. 4,393,105 incorporated herein by this reference.

Preferably, the metal housing component has a sufficiently high yield strength such that it induces compressive stress within the cover glass (e.g., silica glass or sapphire) to increase the tensile strength of the cover glass and to prevent cracking or at least to prevent crack propagation. In one example, the metal component is a metal or metal alloy such as aluminum, 304 and 316 stainless steel, nickel, titanium, and nickel chromium alloys (e.g., “Inconel”) could also be used. At the same time, the metal alloy should be configured (e.g., thin enough) and have a yield strength which is not too high so that the cover glass does not crack on cooling. Yield strengths ranging from 20-40 kpsi may suffice. In other examples, the housing is a multi-layered ceramic enclosure. See Published application No. US 2013/0078398 incorporated herein by this reference. If sapphire is used as the cover glass, oxygen may be ion implanted into the sapphire surface to provide excess oxygen atoms for anodic bonding to occur.

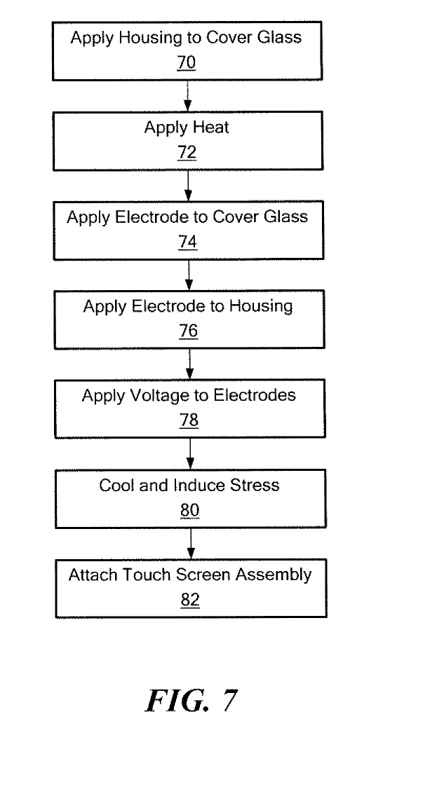

The housing component is preferably applied to the cover glass as depicted in the examples of FIGS. 1-6, step 70, FIG. 7. Heat is applied to the cover glass, step 72 to generate ionic conductivity in the cover glass. A hot plate or an oven may be used. The aluminum housing portion is also heated. The cover glass and housing components may be heated separately and then mated at temperature. During processing, the temperature of the cover glass (and the metal housing component) reaches 350° C. in one specific example. In some examples, temperatures between 250° C. to 450° C. are used. An electrode is applied to the cover glass and an electrode is applied to the housing, steps 74 and 76.

Heating can occur with the electrodes applied, in an oven, for example. The electrodes may be plate electrodes, probes, and/or circumferential “spacer electrodes” 34b shown in FIG. 6 and in U.S. Pat. No. 4,393,105. In FIG. 6, electrode 34a″ is connected to ground while electrode 34b″ is connected to a high voltage source H. The voltage source is turned on, step 78, ramped from zero to peak voltage in 0.5 to 10 minutes, and held at peak voltage (500-2500V) for a dwell time of 1 to 10 minutes while the heat is applied.

A hermetic seal between the housing and the cover glass thus effected via anodic bonding. Thereafter, the voltage and heat are removed and the assembly is allowed to cool, step 80. Because the coefficient of thermal expansion of the aluminum housing (e.g., 22×10⁻⁶/° C.) is much higher than the typical coefficient of thermal expansion of the cover glass (e.g., 8×10⁻⁶/° C.), during the anodic bonding process and during cooling in step 80, the aluminum housing induces compressive stress within the cover glass and increases its tensile strength. Preferably, the housing frame and cover glass are heated separately, mated at the high temperature, anodic bonded, and then cooled.

In FIG. 6, for example, the aluminum housing component 32 expands more than the cover glass 14 when heated and then bonds to the cover glass 14 when voltage Hᵥ is turned on. After the voltage is turned off and the assembly is allowed to cool, aluminum housing component 32 contracts more than the glass and since they are now bonded to each other this causes stress at the bond interfaces 50a, 50b in cover glass 14. Thus, cover glass 14 is strengthened at its corners and about its periphery to avoid cracks (when the electronic device is dropped, for example). Or, if a smart phone is dropped and the cover glass cracks at a corner or edge, crack propagation may be avoided.

In the manufacturing process, the touch screen assembly can then be applied to the cover glass as shown at step 82 in FIG. 7 and the other steps associated with manufacturing a smart phone (or tablet or GPS receiver or the like) can be carried out.

The result is a process which hermetically seals the cover glass to the housing portion and at the same time strengthens at least the periphery of the cover glass.

In other examples, improvements are made in the cover glass/housing interface using anodic bonding techniques even without the heating and cooling steps described above. For example, the anodic bond at the interface between the glass and the housing functions to prevent the propagation of any cracks due to dropping the electronic device and the like. The heating and cooling steps described herein, if used in one preferred embodiment, promote the anodic process and may be varied based on the characteristics of the materials to be bonded. A number of other sequences of heating and applying the voltage are possible, as are variations in the preparation of the glass/and/or metal frame. Example includes turning on the voltage while the heating is ramping up and/or applying a thin film of metal to the edge of the cover substrate or to the metal frame to improve the anodic bonding.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A method comprising:
heating a portable electronic device housing portion;
heating a cover glass to generate ionic conductivity therein;
anodic bonding the cover glass to the housing portion; and
cooling the assembly and inducing compressive stress within the cover glass to increase its tensile strength.

2. The method of claim 1 further including the step attaching a touch screen assembly to the cover glass.

3. The method of claim 1 in which the cover glass includes silica glass.

4. The method of claim 1 in which the cover glass is sapphire.

5. The method of claim 1 in which heating the cover glass includes heating the cover glass to a temperature of 350° C.+/−100° C.

6. The method of claim 1 in which heating occurs in an oven or via a hot plate.

7. The method of claim 1 in which inducing compressive stress within the cover glass includes choosing a housing portion material which has a coefficient of thermal expansion substantially higher than the coefficient of thermal expansion of the cover glass.

8. The method of claim 6 in which inducing compressive stress within the cover glass further includes choosing a housing portion material configuration which does not crack the cover glass during cooling.

9. The method of claim 8 in which the housing portion is made of a metal or metal alloy.

10. The method of claim 1 in which anodic bonding the cover glass to the housing includes placing a first electrode on the cover glass and a second electrode on the housing portion.

11. The method of claim 1 in which the housing portion is side member.

12. The method of claim 1 in which the housing portion is a mounting rail.

13. The method of claim 1 in which the housing portion is a metal frame about the cover glass.

14. A method comprising:
heating a glass portion to generate ionic conductivity therein and heating a portable electronic device housing portion to expand it to a greater extent than the glass portion;
when the housing portion is so expanded, bonding it to the glass portion at the periphery thereof using anodic bonding; and
cooling the assembly and contracting the housing portion to a greater extent than the glass portion to induce compressive stress within the glass portion at the periphery thereof.

15. A portable electronic device comprising:
a housing portion;
a cover glass;
an electrostatic bond between the housing portion and the cover glass at the periphery of the cover glass; and
the housing portion inducing compressive stress within the cover glass at its periphery increasing its tensile strength.

16. The portable electronic device of claim 15 further including a touch screen assembly secured to the cover glass.

17. The portable electronic device of claim 15 in which the cover glass includes silica glass.

18. The portable electronic device of claim 15 in which the housing portion material does not have a very low yield strength.

19. The portable electronic device of claim 15 in which the housing portion is a side member.

20. The portable electronic device of claim 15 in which the housing portion is a mounting rail.

21. A method comprising:
applying a portable electronic device housing portion to a cover glass; and
anodic bonding the cover glass to the housing portion to prevent crack propagation at the cover glass/housing portion interface.
